(19) United States
(12) Patent Application Publication
(10) Pub. No.: US 2006/0231918 A1
(43) Pub. Date: Oct. 19, 2006

(54) Field effect transistor and method for the production thereof

(76) Inventors: Martin Popp, Dresden (DE); Frank Richter, Dresden (DE); Dietmar Temmler, Dresden (DE); Andreas Wich-Glasen, Langebrück (DE)

Correspondence Address: MORRISON & FOERSTER LLP, 1650 TYSONS BOULEVARD, SUITE 300, MCLEAN, VA, 22102, US

(21) Appl. No.: 10/482,328

(22) PCT Filed: Jun. 19, 2002
(86) PCT No.: PCT/EP02/06803

§ 371 Date: Aug. 13, 2004

(30) Foreign Application Priority Data
Jun. 28, 2001 (DE) 101 31 237.7

(51) Int. Cl. H01L 29/00

(52) U.S. Cl. 257/510

(57) ABSTRACT

A transistor is provided which advantageously utilizes a part of the area which, in conventional transistors, is provided for the isolation between the transistors. In this case, the channel width can be enlarged in a self-aligned manner without the risk of short circuits. The field-effect transistor according to the invention has the advantage that it is possible to ensure a significant increase in the effective channel width for the forward current ION compared with previously used, conventional transistor structures, without having to accept a reduction of the integration density that can be attained. Thus, by way of example, the forward current I_{ON} can be increased by up to 50%, without having to alter the arrangement of the active regions or of the trench isolation.

### CLAIM FOR PRIORITY

This application claims priority to PCT/EP02/06803, filed in the German language on Jun. 19, 2002, which claims the benefit to German Application No. DE 101 31237.7, filed in the German language on Jun. 28, 2001.

The present invention relates to a field-effect transistor and a method for fabricating it.

The characteristic parameters of conventional field-effect transistors, in particular of planar MIS field-effect transistors (MISFET), are increasingly impaired with continual structural miniaturization (scaling) and increasing of the packing density of integrated circuits. Thus, by way of example, with a shortened channel length of the transistor the threshold voltage V_{T} of the transistor decreases. At the same time, with a shortened channel length, the field strength in the channel region and the reverse current I_{OFF} increase (SCE: short channel effect; roll-off). Furthermore, with a reduced channel width, the forward current I_{ON} varies in a non-linear manner. In addition, the geometry and doping of the field-effect transistor are modified at the junction between the channel and the insulation. Generally, in the event of scaling, the channel boundaries gain in relative importance with respect to the central channel region (NCE: narrow channel effect, INCE: inverse narrow channel effect).

In order, despite the difficulties mentioned, to be able to ensure an improvement/maintenance of the performance of field-effect transistors in the context of advancing structural miniaturization (scaling), a series of measures are proposed or implemented. Thus, by way of example, a matched scaling of the internal operating voltage levels is effected at the same time as the MISFET scaling. Furthermore, the doping profiles of the well and channel regions and also of the source and drain regions are generally optimized. At the same time, scaling of the gate insulator with regard to thickness and material is usually carried out. Further improvements result from the use of salicided source and drain regions (S/D) and salicided gate electrodes. A further improvement can be obtained by minimization of the parasitic resistances or capacitances of the connection metallization, for example through the use of copper wiring, and of the intermediate insulators, for example through the use of so-called “low-k” materials. In the case of DRAM memory cells, it is also possible to adapt the read-out logic to the “ON” currents—which decrease with each “shrink”—of the respective array transistors (e.g. reduction of the resistances of the gate tracks).

A further possibility for maintaining or improving the performance of field-effect transistors consists in the use of modified transistor arrangements which, for example, have elevated source/drain regions (“elevated S/D”) or which are based on a so-called “silicon on insulator” technology (SOI) or which have a material with a higher carrier mobility, e.g. SiGe, in the channel region. Additional possibilities which result when the operating temperature is lowered are not presented here.

The introduction of the trench field isolation (STI: shallow trench isolation) instead of conventional LOCOS field isolation likewise contributes to improving the situation. If a trench field isolation (STI: shallow trench isolation) is used instead of a conventional LOCOS field isolation, then it is generally necessary to take additional measures to minimize the so-called “inverse narrow channel effect” (INCE). Thus, by way of example, a positive step height of the STI upper edge above the semiconductor surface is set in order to avoid a so-called “wraparound gate”. Furthermore, a local doping of the transistor channel at the junction with the field isolation, the so-called “corner region”, may be provided in addition to the normal channel doping.

Oxidation of the STI sidewalls during the STI processing may result in the production of a so-called “bird's beak geometry” and edge rounding of the active regions at the junction with the trench isolation. In the process sequence, the terms mentioned here are “corner rounding”, “mini LOCOS” or “post CMP oxidation”. These measures also serve to counteract the “inverse narrow channel effect” (INCE). This effect can be reinforced by prior lateral etching-back of the pad oxide. Edge rounding of the active regions can also be produced by means of thermal surface transformation. Furthermore a nitride spacer guard ring may be provided. In order to avoid a gate overlap over the corner region, it is possible to provide a self-aligned termination of the gate edge before the field isolation boundary. This may be done for example by joint patterning of poly-gate and active region during the STI patterning.

Despite all these measures, however, it is becoming more and more difficult to ensure an adequate forward current I_{ON} above a feature size of about 100 nm, without the risk of tunnelling or degradation of the gate oxide stability of the MISFET. Therefore, a series of alternative transistor arrangements have been proposed.

The document U.S. Pat. No. 4,979,014 discloses a MOS transistor having a web-type elevation on a semiconductor substrate. The channel of this transistor is arranged along the web-type elevation and has, besides one channel region at the top side of the web-type elevation, two further channel regions at the sidewalls of the web-type elevation. The transistor in accordance with document U.S. Pat. No. 4,979,014 exhibits a pronounced “corner effect”, which is used to produce a large depletion zone.

The document Huang et al. “Sub 50 nm FinFET; PMOS” IEDM 1999 discloses a transistor called “FinFET”, which has a dual gate structure at the sidewalls of the web-type elevation (“Fin”). The FinFET avoids the INCE by means of a thicker insulator layer on the narrow Fin covering surface.

Unfortunately, all of the measures mentioned either have only limited efficacy or they require a high process engineering outlay. Therefore, it is the object of the present invention to provide a field-effect transistor and a method for fabricating it which reduce or avoid the abovementioned difficulties. In particular, the object of the present invention is to provide a field-effect transistor which makes available an adequate forward current I_{ON} and which can be fabricated with a low outlay, compatibly with the previous conventional integration process for planar MOSFETs.

This object is achieved by the field-effect transistor in accordance with the independent patent claim 1 and by the method for fabricating a field-effect transistor in accordance with the independent patent claim 8. Further advantageous embodiments, refinements and aspects of the present invention emerge from the dependent patent claims, the description and the accompanying drawings.

The invention provides a field-effect transistor comprising the following features:
a) a source region and a drain region,
b) a channel region, which is arranged between the source region and the drain region,
c) a gate electrode, which is arranged above the channel region in a manner electrically insulated from the channel region,
d) a trench isolation, which laterally bounds the channel region,
e) at least one partial region of the channel region covering a part of the trench isolation.

Furthermore, the invention provides a method for fabricating a field-effect transistor comprising the following steps:
a) a semiconductor substrate with at least one active region and an already completed trench isolation is provided,
b) a selective epitaxy is carried out, an essentially monocrystalline semiconductor material being formed above the active region and above a part of the trench isolation, so that a channel region is produced,
c) a gate oxide is produced on the channel region and a gate electrode is produced on the gate oxide, and
d) source and drain regions are produced.

The field-effect transistor according to the invention has the advantage that it is possible to ensure a significant increase in the effective channel width for the forward current I_{ON} compared with previously used, conventional transistor structures, without having to accept a reduction of the integration density that can be attained. Thus, by way of example, the forward current I_{ON} can be increased by up to 50%, without having to alter the arrangement of the active regions or of the trench isolation. The transistor according to the invention advantageously utilizes a part of the area which, in conventional transistors, is provided for the isolation between the transistors. In this case, the channel width can be enlarged in a self-aligned manner without the risk of short circuits.

The field-effect transistor according to the invention or the method according to the invention makes it possible to increase the packing density of patterned, active regions, since the possibilities of the lithography used, also utilizing the exposure of structures which are smaller than the so-called “ground rule”, can be exploited virtually in their entirety. Thus, by way of example, it is possible, given optimal structural occupancy on the wafer (equal dimension for web width and distance between the webs—so-called “equal space—equal line”), to produce smaller active regions and then, however, to process the actual transistor to the required design dimension (in particular channel width).

By way of example, if the intention is to fabricate a transistor in a 110 nm technology (channel width=110 nm), then it is possible to perform exposure or patterning at 90 nm (width of active region: 90 nm, width of trench isolation: 90 nm). A significantly increased integration density is accordingly produced. Afterward, with the aid of the fact that a partial region of the channel region covers a part of the trench isolation, it is possible to produce a transistor having a channel width of 110 nm (as required in the design). The lateral extent of the trench isolation at the surface of the wafer accordingly falls to 70 nm.

The field-effect transistor according to the invention furthermore has the advantage that the “corner” effect brought about geometrically in conventional transistors, on account of field-induced local electron accumulation, can be largely avoided. Furthermore, in the case of the field-effect transistor according to the invention, it is possible to dispense with the previous strong topology between the trench isolation and the channel region. The field-effect transistor according to the invention or the method according to the invention furthermore has the advantage that it can be integrated into different semiconductor technologies (e.g. logic or memory) without a high outlay.

In accordance with a preferred embodiment of the field-effect transistor according to the invention, the channel region is an epitaxially produced semiconductor region. Accordingly, the field-effect transistor has a very good surface for gate oxide, since epitaxially grown surfaces are generally significantly freer of defects than conventional semiconductor surfaces. In accordance with a further preferred embodiment of the field-effect transistor according to the invention, a groove-shaped recess is formed along the upper edge of the trench isolation.

In accordance with a further preferred embodiment, the partial region of the channel region which covers a part of the trench isolation occupies more than 10%, preferably more than 20%, of the channel region. Furthermore, it is preferred if the width of the channel region is greater than 1.2 times, preferably greater than 1.4 times, the minimum feature size F which can be fabricated by the lithography used to fabricate the transistor.

In accordance with a further preferred embodiment of the field-effect transistor according to the invention, the surface of the channel region is arranged below the surface of the trench isolation.

In accordance with a further preferred embodiment of the field-effect transistor according to the invention, the surface of the channel region is arranged above the surface of the trench isolation and the channel region thus has horizontal and vertical regions.

In accordance with a preferred embodiment of the method according to the invention, an etching is carried out before the selective epitaxy in step b), at least one part of the trench isolation that adjoins the active region being etched, so that a groove-shaped recess is produced along the upper edge of the trench isolation. In this case, it is particularly preferred if the part of the trench isolation that adjoins the active region is etched isotropically. Furthermore, it is preferred if, in step a), the surface of the active region is arranged below the surface of the trench isolation.

In accordance with a further preferred embodiment of the method according to the invention, before the production of the gate oxide, a sacrificial oxide is applied, which is subsequently removed again. The use of a sacrificial oxide results in very good through-oxidation of the interface between the part of the channel region that covers the trench isolation and the trench isolation, which is preferably filled with oxide.

In accordance with a further preferred embodiment of the method according to the invention, in step a), an oxide layer is arranged above the active region and the oxide layer on the active region is removed with the etching of the trench isolation, so that a groove-shaped recess is produced along the upper edge of the trench isolation. In this case, it is particularly preferred if the etching of the oxide layer and of the trench isolation is effected selectively with respect to the material of the active region.

In accordance with a preferred embodiment of the method according to the invention, the etching of the trench isolation is ended with the removal of the oxide layer. In accordance with a further preferred embodiment of the method according to the invention, the etching of the trench isolation is also continued after the removal of the oxide layer, so that an extended groove-shaped recess is produced.

In accordance with a further preferred embodiment of the method according to the invention, the selective epitaxy in step b) is carried out in such a way that the surface of the channel region (8) is arranged below the surface (3a) of the trench isolation (3). Furthermore, it is preferred if, after the selective epitaxy, a thermal treatment is carried out for the planarization of the epitaxial surface.

In accordance with a further preferred embodiment of the method according to the invention, the selective epitaxy in step b) is carried out in such a way that the surface of the channel region is arranged above the surface of the trench isolation and the channel region is formed with horizontal and vertical regions.

In accordance with a preferred embodiment of the method according to the invention, monocrystalline silicon is formed by the selective epitaxy.

In accordance with a further preferred embodiment of the method according to the invention, before the selective epitaxy, the active region and the etched part of the trench isolation are measured by means of a scanning force microscope. Furthermore, it is preferred if the etching of the part of the trench isolation that adjoins the active region is effected by a wet-chemical etching.

The invention is explained in more detail below with reference to figures of the drawing, in which:

FIGS. 1-3 show a first embodiment of the method according to the invention for fabricating a field-effect transistor, and

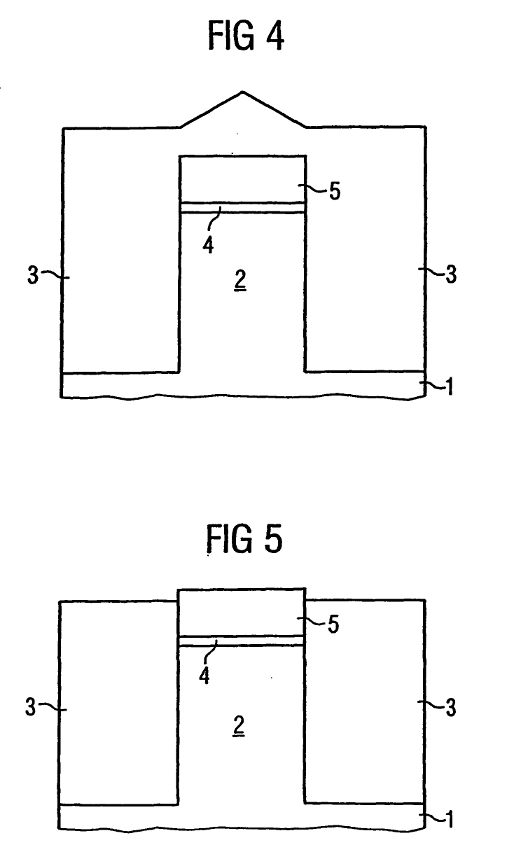

FIGS. 4-7 show a further embodiment of the method according to the invention for fabricating a field-effect transistor,

FIGS. 8-13 show a further embodiment of the method according to the invention for fabricating a field-effect transistor, and

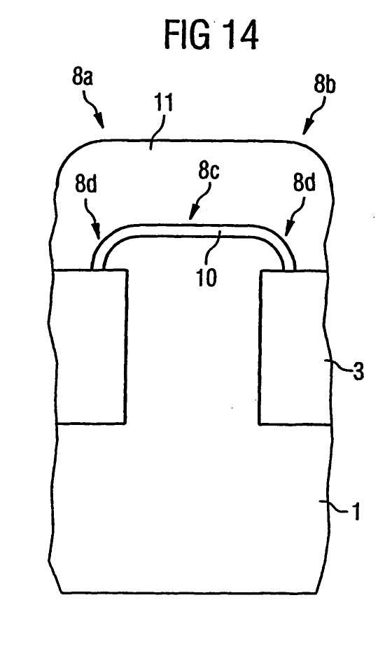

FIG. 14 shows an enlarged view of the field-effect transistor according to the invention as shown in FIG. 13.

FIGS. 1 to 3 show a first embodiment of the method according to the invention for fabricating a field-effect transistor. The starting point of the method according to the invention is a semiconductor substrate 1, for example a silicon substrate, which has active regions 2 and an already completed trench isolation 3 between the active regions 2. For reasons of clarity, only one active region is shown of the many active regions which are typically present in the semiconductor substrate 1. The field-effect transistor is produced hereinafter in the region of the active region.

A pad oxide layer 4 and a pad nitride layer 5 are arranged above the active region. These layers were used inter alia to produce the trench isolation 3. The trench isolation 3 is obtained for example by filling a trench that has been etched into the semiconductor substrate 1 with silicon oxide with the aid of an HDP method (“high density plasma”). In this case, a so-called “liner”, for example a nitride liner (not shown), may additionally be provided between the semiconductor substrate 1 and the oxide filling. After the deposition of the silicon oxide, a CMP step (“chemical mechanical polishing”) is carried out, so that the pad nitride layer 5 is uncovered. The resultant situation is illustrated in FIG. 1.

Since, in the method according to the invention, in contrast to conventional methods, the CMP step does not have to be used for the final setting of the step height between the surfaces 3a of the trench isolation 3 and the lower-lying surface 2a of the active region 2, this CMP step has a significantly enlarged process window in the context of the method according to the invention, which, in turn, has a positive effect on the process stability. A so-called “nitride pullback” of the pad nitride layer 5, required in conventional methods, can be dispensed with in the method according to the invention.

After the pad nitride layer 5 has been removed by a nitride etching, an oxide etching is carried out which etches the oxide of the trench isolation 3 and, in particular, a part of the trench isolation 3 that adjoins the active region 5. At the same time, the pad oxide layer 4 is also removed by this etching. During this etching, a groove-shaped recess 6 is produced along the upper edge of the trench isolation.

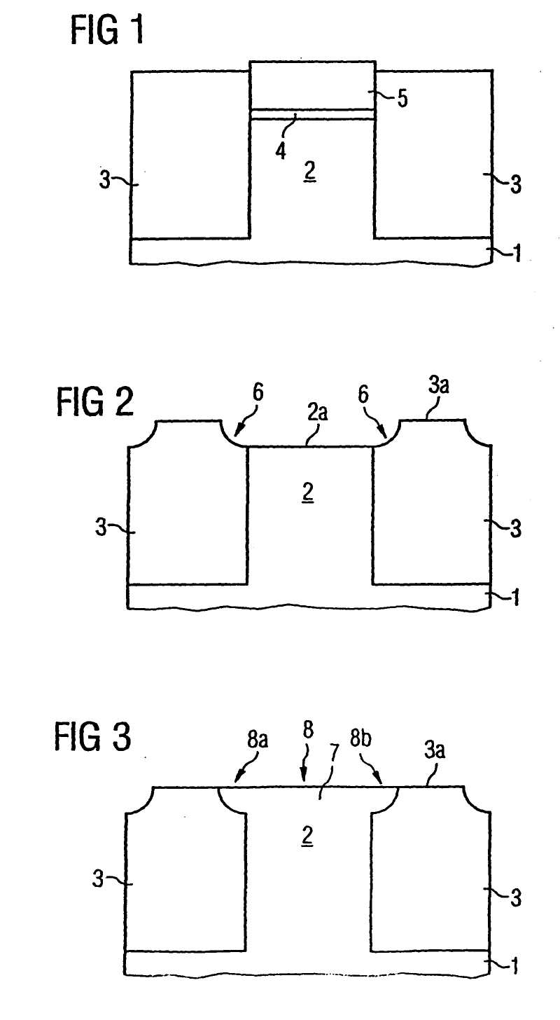

For this etching, a wet-chemical etching is preferably used which etches the pad oxide layer 4 and the oxide of the trench isolation 3 selectively with respect to the active region 2. Such an etching can be carried out for example using buffered HF acid (BHF). In the present example, the etching of the trench isolation 3 is ended with the removal of the pad oxide layer 4. The resultant situation is illustrated in FIG. 2.

In order to set optimal process parameters for the selective epitaxy that is subsequently carried out, the structure shown in FIG. 2 can be measured by means of a scanning force microscope before the selective epitaxy. A selective silicon epitaxy is subsequently carried out, essentially monocrystalline silicon 7 being formed above the active region 2 and above the groove-shaped recess 6 in the trench isolation 3. In this case, the monocrystalline silicon 7 can be doped as early as during the selective silicon epitaxy. However, doping of the monocrystalline silicon 7 can also be carried out after the selective silicon epitaxy. The selective silicon epitaxy produced the regions which will hereinafter form the source/drain regions and, in particular, the channel region 8 of the transistor.

The groove-shaped recess 6 in the trench isolation 3 does not have to be completely filled with silicon during the selective epitaxy. A positive step height can still remain between the monocrystalline silicon 7 and the surface 3a of the trench isolation. Accordingly, the surface of the channel region 8 is arranged below the surface 3a of the trench isolation 3. Compared with the conventional methods, however, the method according to the invention has the advantage that the strong topology differences previously present can be largely or completely eliminated.

The production of the monocrystalline silicon 7 is followed by the production of the gate oxide layer (not shown) and the gate electrode (not shown). After a patterning of the gate electrode, the source and drain regions (not shown) are fabricated by a doping.

It can be seen that the width of the channel region 8 is significantly increased by the partial regions 8a and 8b of the channel region 8 which cover the groove-shaped recess 6 in the trench isolation 3. The method according to the invention thus has the advantage that it is possible to ensure a significant increase in the effective channel width for the forward current ION compared with previously used, conventional transistor structures, without having to accept a reduction of the integration density that can be attained. Thus, by way of example, the forward current ION can be increased by up to 50%, without having to alter the arrangement of the active regions or of the trench isolation. The transistor according to the invention advantageously utilizes a part of the area which, in conventional transistors, is provided for the isolation between the transistors. In this case, the channel width can be enlarged in a self-aligned manner without the risk of short circuits.

FIGS. 4-7 show a further embodiment of the method according to the invention for fabricating a field-effect transistor. The starting point of the method according to the invention is again a semiconductor substrate 1, for example a silicon substrate, which has active regions 2 and an already completed trench isolation 3 between the active regions 2. A pad oxide layer 4 and a pad nitride layer 5 are arranged above the active region. These layers were used inter alia to produce the trench isolation 3. The trench isolation 3 is obtained for example by filling a trench that has been etched into the semiconductor substrate 1 with silicon oxide with the aid of an HDP method (“high density plasma”). FIG. 4 diagrammatically shows a structure as is produced after the HDP method but before a CMP step.

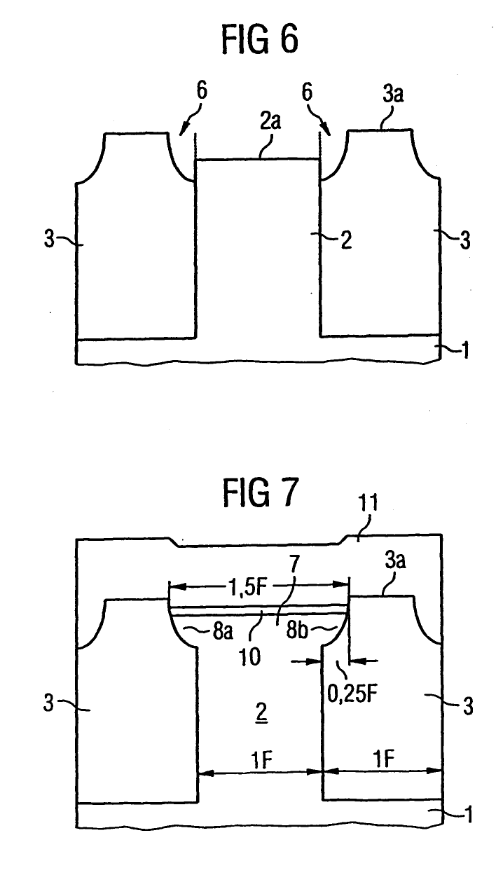

After the deposition of the trench oxide, a CMP step (“chemical mechanical polishing”) is carried out, so that the pad nitride layer 5 is uncovered. The resultant situation is illustrated in FIG. 5. After the pad nitride layer 5 has been removed by a nitride etching, an etching is carried out which removes at least a part of the trench isolation 3 that adjoins the active region 5. At the same time, the pad oxide layer 4 is also removed by this etching. For this etching, a wet-chemical etching is preferably used which etches the pad oxide layer 4 and the oxide of the trench isolation 3 selectively with respect to the active region 2. In the present example, the etching of the trench isolation 3 is also continued after the removal of the pad oxide layer 4, thereby producing a larger lateral extent of the groove-shaped recess 6. The resultant situation is illustrated in FIG. 6.

Afterward, a selective silicon epitaxy is again carried out, essentially monocrystalline silicon 7 being formed above the active region 2 and above the etched part 6 of the trench isolation 3. After the selective epitaxy, a thermal treatment can optionally be carried out, which results in a planarization of the monocrystalline silicon 7.

Before the production of the gate oxide 10, a sacrificial oxide (not shown) is then applied, which is subsequently removed again. The use of a sacrificial oxide results in a very good through-oxidation of the interface between the parts 8a and 8b of the channel region 8 which covers the trench isolation 3 and the oxide of the trench isolation 3. Afterward, the gate oxide layer 10 is produced in a customary manner, onto which the gate electrode 11, for example in the form of a polysilicon layer or in the form of a polycide layer, is in turn deposited (FIG. 7).

The gate electrode or the gate stack 11 is subsequently patterned by an etching, the method according to the invention having the advantage that a previously customary overetch can largely be dispensed with here. In the conventional methods, an overetch was necessary during the patterning of the gate electrode since gate stack regions of different thickness could be present on account of the large topology differences. However, the overetch frequently led to damage to the underlying gate oxide. Since corresponding overetches can largely be avoided in the method according to the invention, it is also possible to ensure a high quality of the gate oxide. After a patterning of the gate electrode, the source and drain regions (not shown) are fabricated by a doping.

It can be seen from FIG. 7 that the partial regions 8a and 8b of the channel region 8 which in each case cover a part 6 of the trench isolation 3 in each case occupy more than 20% of the channel region 8. Accordingly, the width of the channel region is enlarged by more than 40%. Since, in the present example, the width of the active region 2 corresponds approximately to the minimum feature size F which can be fabricated by the lithography used to fabricate the transistor, the width of the channel region 8 is accordingly greater than 1.4 times the minimum feature size F. Thus, the forward current ION can be increased by up to 50%, without having to alter the arrangement of the active regions or of the trench isolation. Furthermore, the method according to the invention has a good controllability, since the profile of the channel region can be set according to the design specifications with the aid of the CMP step, the pad nitride thickness and also the wet-chemical etching.

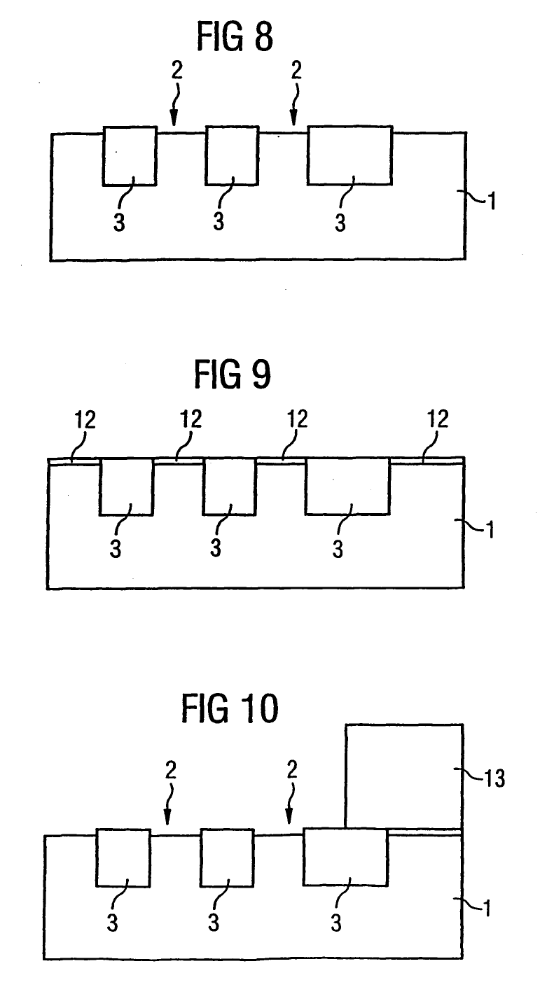

FIGS. 8-13 show a further embodiment of the method according to the invention for fabricating a field-effect transistor. The groove-shaped recess, which is fashioned to a greater or lesser extent in this embodiment, too, is not illustrated in the figures for reasons of clarity. In contrast to the two embodiments described previously, in which the epitaxially formed active surface is arranged slightly below the highest level of the STI surface, in this embodiment the epitaxial growth is effected beyond this level. The starting point of the method according to the invention is again a semiconductor substrate 1, for example a silicon substrate, which has active regions 2 and an already completed trench isolation 3 between the active regions 2 (FIG. 8). An oxidation is subsequently carried out, so that a thin oxide layer 12 is produced on the surface of the active regions 2 (FIG. 9).

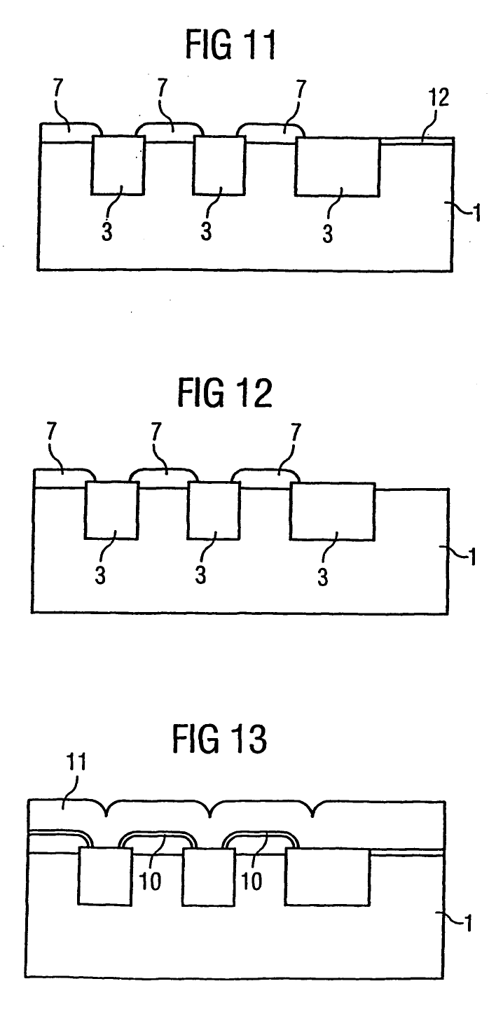

Afterward, said thin oxide layer 12 is removed again (FIG. 10) by means of isotropic etching using a mask 13, which optionally covers all the regions for transistors without intended channel extension. After the removal of the mask 13 and cleaning, an essentially monocrystalline semiconductor layer 7 is deposited on the uncovered semiconductor surfaces by means of selective epitaxy, which layer, at the same time, also laterally overgrows the edge 6 of the trench isolation 3, approximately to the extent of the epitaxial thickness above the STI surface. On account of the laws of epitaxial growth, the upper edge of the epitaxial layer 7 in this case forms in a faceted-rounded manner (FIG. 11). Accordingly, the surface of the channel region 8 is now arranged above the surface 3a of the trench isolation 3.

The removal of the thin oxide layer 12 including on the non-epitaxially-overgrown regions (FIG. 12) is followed by the production of the gate oxide layer 10 and deposition and patterning of the gate electrode layer 11 (FIG. 13). This is followed by the further processing including fabrication of the S/D regions through to the complete circuit according to a conventional process sequence.

Optionally, the oxidation performed after the production of the field isolation and the patterning of said oxidation as oxide block layer 12 can also be omitted, as a result of which all the active regions, thus all types of transistors and other functional elements that are to be integrated on the semiconductor substrate, are formed with a laterally and vertically epitaxially overgrown structure.

FIG. 14 shows an enlarged view of the field-effect transistor according to the invention as shown in FIG. 13. The channel region 8 is again formed below the surface of the epitaxial layer 7. In this case, the partial regions 8a and 8b of the channel region 8 again cover a part 6 of the trench isolation 3. In contrast to the previously shown embodiments of the field-effect transistor according to the invention, the field-effect transistor shown in FIG. 14 has, in addition to the central active horizontal region 8c, active vertical regions 8d which are bounded by the trench isolation 3.

The height difference between the planar surface of the active regions and the surface of the trench isolation approximately corresponds to the width of the vertical channel regions 8d. The doping profile depth of the source and drain regions is preferably greater than said height difference. The relief structure comprising active and STI surface is covered by a gate electrode 11, preferably a polySi-metal layer stack, in the channel region 8. The channel region 8 is covered by a gate oxide 10 on its planar and on its vertical part. The edge of the active region, i.e. the transition from the planar (horizontal) to the vertical part of the surface of the active semiconductor region, is faceted-rounded. In this case, the radius of curvature of this rounding is, for example, of the order of magnitude of the vertical elevation of the active region above the STI surface. The channel region is flanked on the source and drain side by spacers (not shown) which laterally insulate the gate electrode from the S/D contact areas.

1. A field-effect transistor, in particular MIS field-effect transistor, having:
a) a source region and a drain region,
b) a channel region (8), which is arranged between the source region and the drain region,
c) a gate electrode (11), which is arranged above the channel region in a manner electrically insulated from the channel region,
d) a trench isolation (3), which laterally bounds the channel region (8),
e) at least one partial region (8a, 8b) of the channel region (8) covering a part (6) of the trench isolation (3).

2. The field-effect transistor as claimed in claim 1, wherein
the channel region (8) is an epitaxially produced semiconductor region.

3. The field-effect transistor as claimed in claim 1, wherein
a groove-shaped recess is formed along the upper edge of the trench isolation.

4. The field-effect transistor as claimed in claim 1, wherein
the partial region (8a, 8b) of the channel region (8) which covers a part (6) of the trench isolation (3) occupies more than 10%, preferably more than 20%, of the channel region.

5. The field-effect transistor as claimed in claim 1, wherein
the width of the channel region (8) is greater than 1.2 times, preferably greater than 1.4 times, the minimum feature size F which can be fabricated by the lithography used to fabricate the transistor.

6. The field-effect transistor as claimed in claim 1, wherein
the surface of the channel region (8) is arranged below the surface (3a) of the trench isolation (3).

7. The field-effect transistor as claimed in claim 1, wherein
the surface of the channel region (8) is arranged above the surface (3a) of the trench isolation (3) and the channel region (8) has horizontal and vertical regions (8c, 8d).

8. A method for fabricating a field-effect transistor, in particular a MIS field-effect transistor, having the following steps:
a) a semiconductor substrate (1) with at least one active region (2) and an already completed trench isolation (3) is provided,
b) a selective epitaxy is carried out, an essentially monocrystalline semiconductor material (7) being formed above the active region (2) and above a part (6) of the trench isolation (3), so that a channel region (8) is produced,
c) a gate oxide (10) is produced on the channel region (8) and a gate electrode (11) is produced on the gate oxide (10), and
d) source and drain regions are produced.

9. The method as claimed in claim 6, wherein
an etching is carried out before the selective epitaxy in step b), at least one part (6) of the trench isolation (3) that adjoins the active region (2) being etched, so that a groove-shaped recess is produced along the upper edge of the trench isolation (3).

10. The method as claimed in claim 7, wherein
the part (6) of the trench isolation (3) that adjoins the active region (2) is etched isotropically.

11. The method as claimed in claim 7, wherein
in step a), an oxide layer (4) is arranged above the active region (2) and the oxide layer (4) on the active region (2) is removed with the etching of the trench isolation, so that a groove-shaped recess is produced along the upper edge of the trench isolation (3).

12. The method as claimed in claim 9, wherein
the etching of the trench isolation (3) is ended with the removal of the oxide layer (4).

13. The method as claimed in claim 9, wherein
the etching of the trench isolation (3) is also continued after the removal of the oxide layer (4).

14. The method as claimed in claim 9, wherein
the etching of the oxide layer (4) and of the trench isolation (3) is effected selectively with respect to the material of the active region (2).

15. The method as claimed in claim 6, wherein
the selective epitaxy in step b) is carried out in such a way that the surface of the channel region (8) is arranged below the surface (3a) of the trench isolation (3).

16. The method as claimed in claim 13, wherein
after the selective epitaxy, a thermal treatment is carried out for the planarization of the epitaxial surface.

17. The method as claimed in claim 6, wherein
the selective epitaxy in step b) is carried out in such a way that the surface of the channel region (8) is arranged above the surface (3a) of the trench isolation (3) and the channel region (8) is formed with horizontal and vertical regions (8c, 8d).

18. The method as claimed in claim 6, wherein
monocrystalline silicon is formed by the selective epitaxy.

19. The method as claimed in claim 7, wherein
before the selective epitaxy, at least the active region (2) and the etched part (6) of the trench isolation (3) are measured by means of a scanning force microscope.

20. The method as claimed in claim 7, wherein
the etching of the part (6) of the trench isolation (3) that adjoins the active region (2) is effected by a wet-chemical etching.

21. The method as claimed in claim 6, wherein
before the production of the gate oxide (10), a sacrificial oxide is applied and removed again.
